(19) United States
(12) Patent Application Publication
(10) Pub. No.: US 2015/0108648 A1
(43) Pub. Date: Apr. 23, 2015

(54) SEMICONDUCTOR DEVICE AND METHOD OF MANUFACTURING THE SAME

(71) Applicant: KABUSHIKI KAISHA TOSHIBA, Tokyo (JP)

(72) Inventors: Kazumichi TSUMURA, Oita Oita (JP); Kazuyuki HIGASHI, Oita Oita (JP)

(21) Appl. No.: 14/474,301

(22) Filed: Sep. 2, 2014

(30) Foreign Application Priority Data
Oct. 18, 2013 (JP) 2013-217151

(51) Int. Cl. H01L 23/00

(52) U.S. Cl. CPC H01L 24/09; H01L 24/89; H01L 2224/05147; H01L 2924/01104; H01L 2924/0549; H01L 2224/08145; H01L 2224/80801; H01L 2224/05573
USPC 257/751; 438/107

(57) ABSTRACT

A semiconductor device includes first and second semiconductor members and a first barrier film. The first semiconductor member includes a first insulating film, and a first wiring film in the first insulating film, the surface of which is exposed in the first insulating film. The second semiconductor member includes a second insulating film, and a second wiring film in the second insulating film, the surface of which is exposed in the second insulating film. The first barrier film forms a barrier to diffusion of the material of the first wiring film into the second insulating film and is formed of a compound of metal element of the first wiring film and an element of the second insulating film in a region where the first wiring film and the second insulating film are in contact with each other at the junction interface of the first and second semiconductor members.

### CROSS-REFERENCE TO RELATED APPLICATION

This application is based upon and claims the benefit of priority from Japanese Patent Application No. 2013-217151, filed Oct. 18, 2013, the entire contents of which are incorporated herein by reference.

### FIELD

Embodiments described herein relate generally to a semiconductor device and a method of manufacturing the semiconductor device.

### BACKGROUND

In the related art, there has been developed a technology (Wafer-to-Wafer (W2W)/Metal Bonding) for bonding a plurality of semiconductor substrates (wafers), thereby joining together electrodes formed on the surfaces of the semiconductor substrates. In general, electrodes are formed on the surface of a semiconductor substrate such that the electrodes extend into an inter-layer insulating film, and the surfaces of the electrodes are exposed at the surface of the inter-layer insulating film. Further, on the occasion of bonding the semiconductor substrates together, the semiconductor substrates to be bonded are aligned such that the electrodes of the semiconductor substrates are joined together.

However, it is difficult to align semiconductor substrates such that the positions of the electrodes of each substrate completely coincide with the positions of corresponding electrodes of another substrate. In the corresponding technical field, there has been proposed a technology for suppressing diffusion of Cu into an interlayer insulating film. As this technology, for example, a method of forming a barrier film of a material such as SiN on the surface of a semiconductor substrate except for the surface of the exposed Cu electrodes such that the barrier film suppresses diffusion of Cu into the interlayer insulating film has been proposed. Additionally, a method of forming an insulating film of a material such as benzocyclobutene (BCB) for suppressing diffusion of Cu such that the insulating film insulates a Cu electrode has also been proposed.

### DESCRIPTION OF THE DRAWINGS

FIG. 1 is a cross-sectional view illustrating a portion, including the junction interface of bonded semiconductor members, of a semiconductor device according to an embodiment.

FIG. 2 is a cross-sectional view illustrating a state where an interlayer insulating film has been formed for forming a first semiconductor member.

FIG. 3 is a cross-sectional view illustrating a state where a resist film has been formed for forming the first semiconductor member.

FIG. 4 is a cross-sectional view illustrating a state where patterns have been formed in the resist film for forming the first semiconductor member.

FIG. 5 is a cross-sectional view illustrating a state where groove patterns have been formed in the interlayer insulating film for forming the first semiconductor member.

FIG. 6 is a cross-sectional view illustrating a state where the resist film has been removed for forming the first semiconductor member.

FIG. 7 is a cross-sectional view illustrating a state where a third diffusion suppressing film has been formed for forming the first semiconductor member.

FIG. 8 is a cross-sectional view illustrating a state where a seed layer has been formed for forming the first semiconductor member.

FIG. 9 is a cross-sectional view illustrating a state where the top surface of the seed layer has been plated for forming the first semiconductor member.

FIG. 10 is a cross-sectional view illustrating a state where a wiring connection portion has been formed for forming the first semiconductor member.

FIG. 11 is a cross-sectional view illustrating the first semiconductor member and a second semiconductor member bonded to each other.

FIG. 12 is a cross-sectional view illustrating the first semiconductor member and the second semiconductor member bonded to each other.

FIG. 13 is a cross-sectional view illustrating a first semiconductor member and a second semiconductor member bonded to each other according to another embodiment.

### DETAILED DESCRIPTION

A method of manufacturing a semiconductor device capable of easily improving the electrical characteristics and reliability of the semiconductor device, and a semiconductor device manufactured by the corresponding manufacturing method are provided herein.

In general, according to one embodiment, a semiconductor device includes a first semiconductor member, a second semiconductor member, and a first barrier film. The first semiconductor member includes a first insulating film, and a first wiring film in the first insulating film, the surface of which is exposed in the first insulating film. The second semiconductor member includes a second insulating film, and a second wiring film in the second insulating film, the surface of which is exposed in the second insulating film. The first barrier film forms a barrier to diffusion of the material of the first wiring film into the second insulating film and is formed of a compound of a metal element of the first wiring film and an element of the second insulating film in a region where the first wiring film and the second insulating film are in contact with each other, at the junction interface of the first semiconductor member and the second semiconductor member.

Hereinafter, a semiconductor device according to an embodiment will be described with reference to the accompanying drawings. The semiconductor device according to the present embodiment is configured by bonding a plurality of semiconductor substrates, and may substitute for an existing semiconductor device such as an arithmetic device or a memory device. Each semiconductor substrate to be bonded includes an electronic circuit composed of a single layer structure or a multi-layer structure of circuit elements such as transistors and wiring films connecting the circuit elements. When the semiconductor substrates are bonded, a wiring film formed on a surface of one semiconductor substrate is joined with a wiring film formed on a surface of the other semiconductor substrate, whereby the electronic circuits formed in the individual semiconductor devices are electrically connected to each other. Also, the semiconductor device may have through-electrodes formed through the plurality of semiconductor substrates constituting the semiconductor device.

In the related art, when electrodes are formed, irregularity in their shape or size may occur due to manufacturing errors. In this case, on the occasion of bonding a plurality of semiconductor substrates, it is difficult to align the semiconductor substrates such that the position of each electrode completely coincides with the position of a corresponding electrode, and an error in joining in a bonding process may occur attributable to this misalignment. For this reason, when semiconductor substrates are bonded, misalignment may occur such that electrodes of one semiconductor substrate come into contact with an interlayer insulating film of the other semiconductor substrate. Further, for example, in a case where the electrodes are Cu electrodes formed using Cu as a main component, at the contact locations of the electrodes and the interlayer insulating film, Cu contained in the electrode may diffuse into the interlayer insulating film, thereby degrading the electric characteristics and reliability of the resulting semiconductor device.

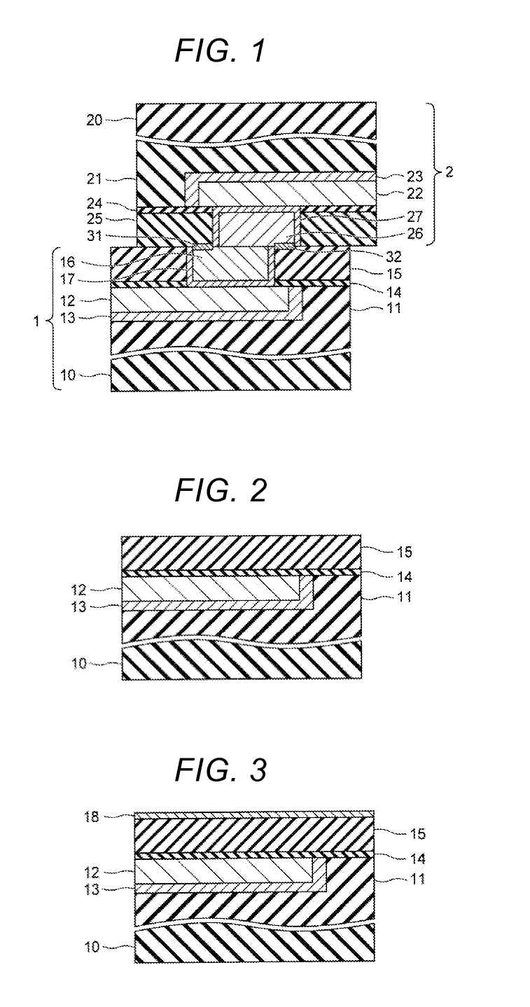

FIG. 1 is a cross-sectional view illustrating a portion, including the peripheral portion the junction interface of bonded semiconductor substrates of a semiconductor device according to an embodiment. As illustrated in FIG. 1, the semiconductor device according to the present embodiment includes a first semiconductor member 1 (the lower side of FIG. 1), a second semiconductor member 2 (the upper side of FIG. 1) bonded to the first semiconductor member 1, and first barrier films 31 and second barrier films 32 formed at the junction interface of the first semiconductor member 1 and the second semiconductor member 2. In the case of the semiconductor device illustrated in FIG. 1, when the first semiconductor member 1 and the second semiconductor member 2 have been bonded together, at a misalignment location, whereby the first barrier films 31 and the second barrier films 32 have been formed at the misaligned locations.

(Configuration of First Semiconductor Member)

First, the configuration of the first semiconductor member 1 will be described. The first semiconductor member 1 is made by forming a single layer structure or multi-layer structure of an electronic circuit on a semiconductor substrate (a first substrate), and includes the semiconductor substrate 10, an insulating film 11, wiring portions 12, a first diffusion suppressing film 13, a second diffusion suppressing film 14, an interlayer insulating film 15 (a first insulating film), wiring connection portions 16 (a first wiring film), and a third diffusion suppressing film 17.

The insulating film 11 is formed on the semiconductor substrate 10 of an insulator such as SiO₂. Although not illustrated, the insulating film 11 includes the single layer structure or multi-layer structure of the electronic circuit therein. As illustrated in FIG. 1, the semiconductor substrate 10 of the first semiconductor member 1 is positioned below the insulating film 11.

The wiring portions 12 are buried in the surface of the insulating film 11 opposite to the semiconductor substrate 10 so as to be electrically connected to the electronic circuit and circuit elements formed in the insulating film 11. The wiring portions 12 are formed so as to extend in a predetermined direction as illustrated in FIG. 1 and be flush with the outer surface of the insulating film 11. The wiring portions 12 contain Cu as a main component (50 atomic percent or more of the composition).

The first diffusion suppressing film 13 is formed between the insulating film 11 and the wiring portions 12. The first diffusion suppressing film 13 is a thin film for suppressing diffusion of Cu contained in the wiring portions 12 into the insulating film 11, and is formed of a conductor such as Ti, Ta, Ru, or a nitride of Ti, Ta, or Ru (TiN, TaN, or RuN).

The second diffusion suppressing film 14 is a thin film for suppressing diffusion of Cu contained in the wiring portions 12 into the interlayer insulating film 15, and is formed so as to cover the exposed surfaces of the wiring portions 12 in the insulating film 11. Where the second diffusion suppressing film 14 is formed to cover the entire surfaces of the insulating film 11 and the wiring portions 12 as illustrated in FIG. 1, the second diffusion suppressing film 14 is formed of an insulator such as SiC, SiN, or SiCN. Therefore, it is possible to prevent a short circuit between the plurality of wiring portions 12 adjacent to each other in the direction of the plane of FIG. 1 via the diffusion suppression film 14.

The interlayer insulating film 15 is formed on the second diffusion suppressing film 14, that is, on a surface of the second diffusion suppressing film 14 on the junction interface side of the first semiconductor member 1. The interlayer insulating film 15 is an insulating film which is formed of a compound of Si, C, or F, with Oxygen. As the interlayer insulating film 15, for example, an oxide film containing SiO₂ or SiOC as a main component may be used.

The wiring connection portions 16 are formed so as to be buried in the interlayer insulating film 15 with the surfaces of the wiring connection portions 16 exposed at the surface of the interlaying insulating film 15. Further, the surfaces of the wiring connection portions 16 are formed so as to be flush with the surface of the interlayer insulating film 15. The wiring connection portions 16 act as electrodes which connect wiring lines (electronic circuits) formed on the semiconductor substrates when the semiconductor substrates are bonded together. The surface shapes of the wiring connection portions 16 may be appropriately selected according to a condition for necessary contact resistance or a design rule. The wiring connection portions 16 contain Cu as a main component.

During manufacturing the first semiconductor member 1, a predetermined metal element α is added to the wiring connection portions 16. During joining of the semiconductor device, the metal element α reacts with predetermined elements contained in an interlayer insulating film 25 of the second semiconductor member 2 (to be described below), whereby the first barrier films 31 are formed. Therefore, in the case where the metal element α added to the wiring connection portions 16 completely reacts during joining of the semiconductor members 1, 2, when the first barrier films 31 are formed, the wiring connection portions 16 of the completed semiconductor device do not contain the metal element α. Meanwhile, in a case where only a part of the metal element α added to the wiring connection portions 16 reacts during joining of the semiconductor members 1, 2, when the first barrier films 31 are formed, the wiring connection portions 16 of the completed semiconductor device contain the remaining metal element α having not reacted. The metal element α is at least one metal element selected from a group composed of Mn, V, Zn, Nb, Zr, Cr, Y, Tc, and Re. As the metal element α, a plurality of metal elements may be selected from this group.

The third diffusion suppressing film 17 is a thin film for suppressing diffusion of Cu contained in the wiring connection portions 16 into the interlayer insulating film 15, and is formed between the interlayer insulating film 15 and the wiring connection portions 16. The wiring connection portions 16 are electrically connected to the wiring portions 12 through the third diffusion suppressing film 17. The third diffusion suppressing film 17 is formed of a conductor such as Ti, Ta, Ru, or a nitride of Ti, Ta, or Ru (TiN, TaN, or RuN).

(Configuration of Second Semiconductor Member)

Subsequently, the configuration of the second semiconductor member will be described. The second semiconductor member 2 is made by forming a single layer structure or multi-layer structure of an electronic circuit on a semiconductor substrate 20 (a second substrate), and includes the semiconductor substrate 20, an insulating film 21, wiring portions 22, a first diffusion suppressing film 23, a second diffusion suppressing film 24, an interlayer insulating film 25 (a second insulating film), wiring connection portions 26 (a second wiring film), and a third diffusion suppressing film 27.

The insulating film 21 is formed on the semiconductor substrate 20 of an insulator such as SiO₂ disposed on the semiconductor substrate 20. Although not illustrated, the insulating film 21 includes therein a single layer structure or multi-layer structure of an electronic circuit. As illustrated in FIG. 1, the semiconductor substrate 20 of the second semiconductor member 2 is positioned on the insulating film 21.

The wiring portions 22 are buried in the surface of the insulating film 21 opposite to the semiconductor substrate 20 so as to be electrically connected to the electronic circuit and circuit elements formed in the insulating film 21. The wiring portions 22 are formed so as to extend in a predetermined direction as illustrated in FIG. 1 and be flush with the outer surface of the insulating film 21. The wiring portions 22 contain Cu as a main component thereof.

The first diffusion suppressing film 23 is formed between the insulating film 21 and the wiring portions 22. The first diffusion suppressing film 23 is a thin film for suppressing diffusion of Cu contained in the wiring portions 22 into the insulating film 21, and is formed of a conductor such as Ti, Ta, Ru, or a nitride of Ti, Ta, or Ru (TiN, TaN, or RuN).

The second diffusion suppressing film 24 is a thin film for suppressing diffusion of Cu contained in the wiring portions 22 into the interlayer insulating film 25, and is formed so as to cover the surfaces of the wiring portions 22 opposite to the semiconductor substrate 20. In a case of forming the second diffusion suppressing film 24 so as to cover the entire surfaces of the insulating film 21 and the wiring portions 22 as illustrated in FIG. 1, the second diffusion suppressing film 24 is formed of an insulator such as SiC, SiN, or SiCN. Therefore, it is possible to prevent a short circuit between the plurality of wiring portions 22 adjacent to each other in the direction of the plane of FIG. 1 via the diffusion suppression film 24.

The interlayer insulating film 25 is formed on the second diffusion suppressing film 24, that is, on a surface of the second diffusion suppressing film 24 on the junction interface side of the second semiconductor member 2. Therefore, the surface of the interlayer insulating film 25 comes into contact with at least some portions of the surfaces of the interlayer insulating film 15 and, where misalignment occurs between connection portions 16 and 26, portions of the wiring connection portions 16 of the first semiconductor member 1. The interlayer insulating film 25 is formed of a compound of Si, C, F, or the like with Oxygen. As the interlayer insulating film 25, for example, an oxide film containing SiO₂ or SiOC as a main component may be used. Also, the main component of the interlayer insulating film 25 may be the same as or different from the main component of the interlayer insulating film 15. For example, the main component of the interlayer insulating film 15 may be SiOC, and the main component of the interlayer insulating film 25 may be SiO₂.

The wiring connection portions 26 are formed so as to be buried in the interlayer insulating film 25 with the surfaces of the wiring connection portions 26 exposed at the outer surface thereof. Further, the surfaces of the wiring connection portions 26 are formed in at least some portions of the interlayer insulating film 25 so as to be flush with the outer surface of the interlayer insulating film 25. The wiring connection portions 26 act as electrodes which connect the wiring lines (the electronic circuits) formed on the semiconductor substrates when the semiconductor substrates are bonded. The surfaces of the wiring connection portions 26 are joined with the wiring connection portions 16 of the first semiconductor member 1 so as to be in contact with at least some portions of the surface of the interlayer insulating film 15. The joining of the wiring connection portions 26 and the wiring connection portions 16 causes the electronic circuit formed in the first semiconductor member 1 to be electrically connected to the electronic circuit formed in the second semiconductor member 2. The surface shapes of the wiring connection portions 26 may be appropriately selected according to a condition for necessary contact resistance or a design rule. The wiring connection portions 26 contain, for example, Cu as a main component.

During manufacturing the second semiconductor member 2, a predetermined metal element β is added to the wiring connection portions 26. During joining of the semiconductor members 1,2, the metal element β reacts with predetermined elements contained in the interlayer insulating film 15 of the first semiconductor member 1, whereby the second barrier films 32 are formed. Therefore, in the case where the metal element β added to the wiring connection portions 26 completely reacts during joining of the semiconductor members 1,2 when the second barrier films 32 are formed, the wiring connection portions 26 of the completed semiconductor device do not contain the metal element β. In a case where only a part of the metal element β added to the wiring connection portions 26 reacts during joining of the semiconductor members 1,2 when the second barrier films 32 are formed, the wiring connection portions 26 of the completed semiconductor device contain the remaining metal element β having not reacted. The metal element β is at least one metal element selected from a group composed of Mn, V, Zn, Nb, Zr, Cr, Y, Tc, and Re. As the metal element p, a plurality of metal elements may be selected from this group. Also, the above described metal element β may be the same as or different from the metal element α which is added to the wiring connection portions 16 during manufacturing the first semiconductor member 1.

The third diffusion suppressing film 27 is a thin film for suppressing diffusion of Cu contained in the wiring connection portions 26 into the interlayer insulating film 25, and is formed between the interlayer insulating film 25 and the wiring connection portions 26. The wiring connection portions 26 are electrically connected to the wiring portions 22 through the third diffusion suppressing film 27. The third diffusion suppressing film 27 is formed of a conductor such as Ti, Ta, Ru, or a nitride of Ti, Ta, or Ru (TiN, TaN, or RuN).

(Configurations of Barrier Films)

Subsequently, the first barrier films 31 and the second barrier films 32 will be described. The first barrier films 31 are formed in regions (misaligned portions), where the surfaces of the wiring connection portions 16 of the first semiconductor member 1 and the surface of the interlayer insulating film 25 of the second semiconductor member 2 are in contact with each other, at the junction interface of the first semiconductor member 1 and the second semiconductor member 2. The first barrier films 31 are thin films for suppressing diffusion of Cu contained in the wiring connection portions 16 into the interlayer insulating film 25, and is formed of the metal element α added to the wiring connection portions 16 and the predetermined elements contained in the interlayer insulating film 25, in a self-aligning way during manufacturing the semiconductor device. Also, in a case where a misalignment has not occurred during bonding of the first semiconductor member 1 and the second semiconductor member 2, that is, in a case where there are no regions (misaligned portions) where the wiring connection portions 16 and the interlayer insulating film 25 are in contact with each other, the first barrier films 31 are not formed.

The first barrier films 31 contain at least one compound selected from a group composed of αₓO_{y}, αₓSi_{y}O_{z}, αₓC_{y}O_{z}, and αₓF_{y}O_{z}. A compound which is contained in the first barrier films 31 depends upon the metal element α and elements contained in the interlayer insulating film 25. For example, in a case where the metal element α is Mn, and the main component of the interlayer insulating film 25 is SiO₂, the composition of the first barrier films 31 becomes MnSiOx. Also, in a case where a plurality of kinds of metal elements is added as the metal element α to the wiring connection portions 16, the first barrier films 31 may contain compounds of the plurality of kinds of elements.

The second barrier films 32 are formed in regions (misaligned portions), where the surfaces of the wiring connection portions 26 of the second semiconductor member 2 and the surface of the interlayer insulating film 15 of the first semiconductor member 1 are in contact with each other, at the junction interface of the first semiconductor member 1 and the second semiconductor member 2. The second barrier films 32 are thin films for suppressing diffusion of Cu contained in the wiring connection portions 26 into the interlayer insulating film 15, and is formed of the metal element β added to the wiring connection portions 26 and the predetermined elements contained in the interlayer insulating film 15, during manufacturing the semiconductor device where misalignment has occurred and the wiring connection portions 26 of second semiconductor member contact the interlayer insulation film 15 of the first semiconductor member 1. Also, in a case where a misalignment has not occurred during bonding of the first semiconductor member 1 and the second semiconductor member 2, that is, in a case where there are no regions (misaligned portions) where the wiring connection portions 26 and the interlayer insulating film 15 are in contact with each other, the second barrier films 32 are not formed.

The second barrier films 32 contain at least one compound selected from a group composed of βₓO_{y}, βₓSi_{y}O_{z}, βₓC_{y}O_{z}, and βₓF_{y}O_{z}. A compound which is contained in the second barrier films 32 changes in accordance with the metal element β and elements contained in the interlayer insulating film 15. For example, in a case where the metal element β is Mn, and the main component of the interlayer insulating film 15 is SiOC, the composition of the second barrier films 32 becomes MnSiOx. Also, in a case where a plurality of kinds of metal elements is added as the metal element β to the wiring connection portions 26, the second barrier films 32 may contain compounds of the plurality of kinds of elements. Also, in a case where the metal element α and the metal element β are different from each other, or in a case where the predetermined elements contained in the interlayer insulating film 15 are different from the predetermined elements contained in the interlayer insulating film 25, different compounds may be contained in the first barrier films 31 and the second barrier films 32, respectively.

As described above, the semiconductor device according to the present embodiment has the barrier films formed in the regions (misaligned portions) where the wiring connection portions and the interlayer insulating films are in contact with each other such that they suppress diffusion of Cu from the wiring portions 16, 26 into the interlayer insulating films 15, 25. Therefore, even in a case where a misalignment has occurred during bonding of the first semiconductor member 1 and the second semiconductor member 2, it is possible to suppress diffusion of Cu into the interlayer insulating films. Therefore, it is possible to suppress a short circuit attributable to Cu having been diffused into the interlayer insulating films, and to improve the electrical characteristics and the reliability.

(Method of Manufacturing Semiconductor Device)

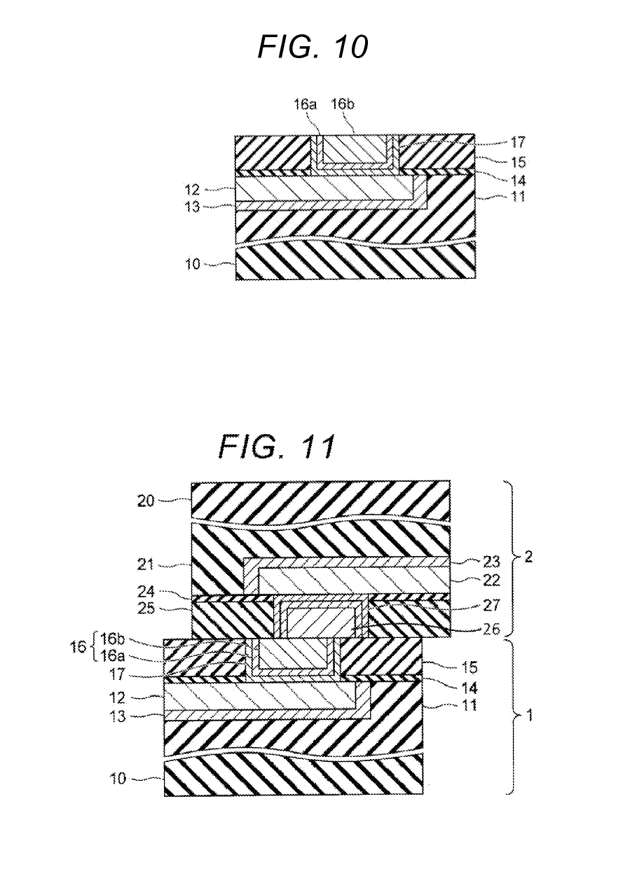

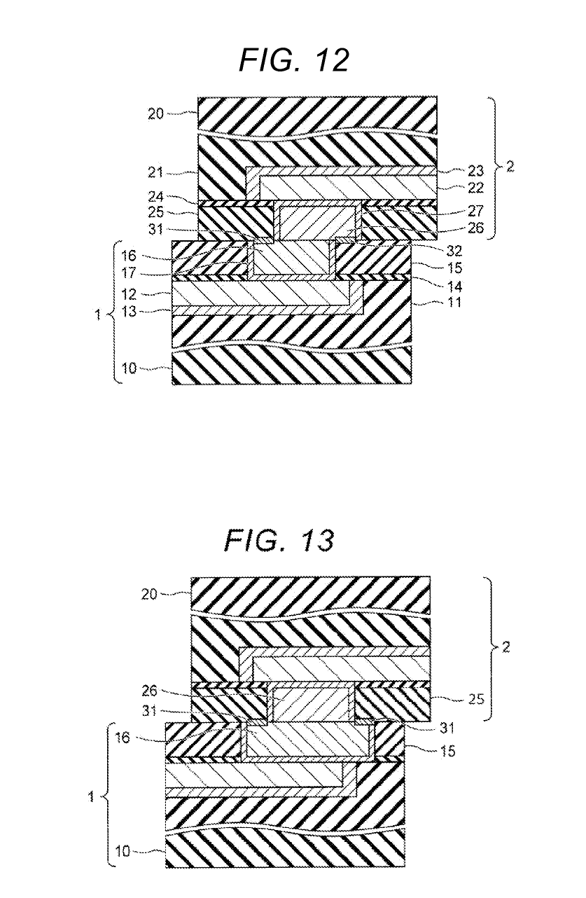

Subsequently, a method of manufacturing the semiconductor device according to the present embodiment will be described with reference to FIGS. 2 to 12. FIGS. 2 to 10 are cross-sectional views illustrating the peripheral portion including the junction interface during manufacturing the first semiconductor member 1, and FIGS. 11 and 12 are cross-sectional views illustrating the peripheral portion including the junction interface of the first semiconductor member 1 and the second semiconductor member 2 bonded to each other.

First, a method of forming the first semiconductor member 1 will be described. On the semiconductor substrate 10 of the first semiconductor member 1, the insulating film 11, the wiring portions 12, the first diffusion suppressing film 13, and the second diffusion suppressing film 14 are formed by technologies such as chemical vapor deposition (CVD), sputtering, lithography, etching, plating, and chemical mechanical polishing (CMP). In this case, the exposed surfaces of the insulating film 11 and the wiring portions 12 are formed so as to be flush with each other.

Subsequently, above the surface of the semiconductor substrate 10, that is, on the second diffusion suppressing film 14, the interlayer insulating film 15 is formed as illustrated in FIG. 2. In this case, as the interlayer insulating film 15, an oxide film may be formed using a CVD method to form. SiO₂, SiOC, or the like as a main component on the second diffusion suppressing film 14.

Subsequently, on the interlayer insulating film 15, a resist film 18 is formed as illustrated in FIG. 3. In this case, a resist (a photosensitive coating material) may be applied to the interlayer insulating film 15 by spin coating or spraying, and be heated (pre-baked) so as to be solidified, whereby the resist film 18 may be formed.

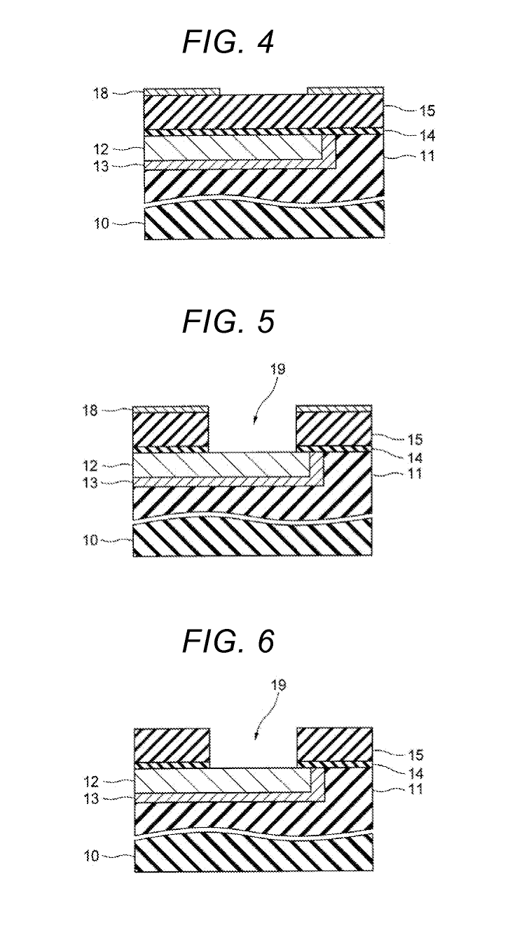

Subsequently, in the resist film 18, patterns for forming the wiring connection portions 16 are created by photolithography as illustrated in FIG. 4. Specifically, the resist film 18 may be irradiated with an exposing electromagnetic source such as light (for example, an excimer laser beam) according to the material of the resist film 18 and the sizes of the patterns, through a photomask located on or over the resist film 18, whereby the patterns for the wiring connection portions 16 may be formed.

Subsequently, a dry etching process is performed using the resist film 18 as a mask, as illustrated in FIG. 5. By the dry etching process, the interlayer insulating film 15 and the second diffusion suppressing film 14 are removed at the openings in the resist layer 18 such that groove patterns 19 (openings) for forming the wiring connection portions 16 is formed. The groove patterns 19 are formed such that the surfaces of the underlying wiring portions 12 are exposed at the base of the groove patterns 19.

Subsequently, the resist film 18 remaining on the interlayer insulating film 15, and residual material generated in the dry etching process, are removed as illustrated in FIG. 6. Specifically, an asking process using oxygen plasma, or a cleaning process using a chemical for dissolving the resist is performed.

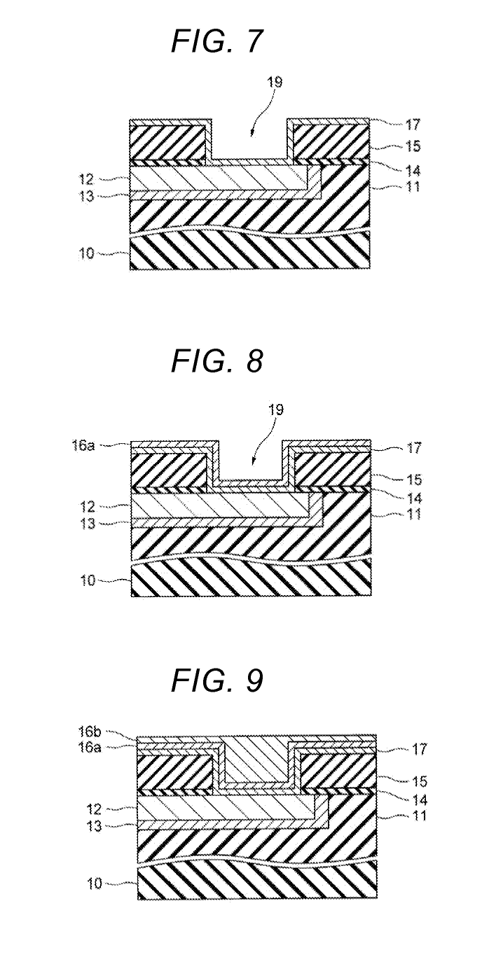

Subsequently, on the inner walls of the groove patterns 19, the third diffusion suppressing film 17 is formed as illustrated in FIG. 7. As the third diffusion suppressing film 17, a film may be formed of Ti, Ta, Ru, or a nitride of Ti, Ta, or Ru (TiN, TaN, or RuN) in an Ar/N₂ atmosphere by a sputtering process.

Subsequently, inside the groove patterns 19, the wiring connection portions 16 are formed by an electroplating method. In order to form the wiring connection portions 16, first, a seed layer 16a is formed on the third diffusion suppressing film 17 as illustrated in FIG. 8. As the seed layer 16a, a layer may be formed of Cu with the above described metal element a added thereto, on the third diffusion suppressing film 17 by a sputtering process.

Subsequently, on the seed layer 16a, a wiring connection portion 16b is deposited as illustrated in FIG. 9 by the electroplating method. The wiring connection portion 16b contains Cu as a main component, and does not contain the metal element α. In this stage, the wiring connection portions 16 form a two-layer structure of the seed layer 16a and the wiring connection portion 16b.

Also, in this stage, the wiring connection portions 16 contain Cu as a main component, and may contain the metal element α added thereto. For example, the seed layer 16a may not contain the metal element α, but the wiring connection portion 16b may contain the metal element α. Alternatively, both of the seed layer 16a and the wiring connection portion 16b may contain the metal element α.

Subsequently, by a method such as CMP, extraneous portions (the portions thereof extending above the outer surface of the interlayer insulating film 15) of the third diffusion suppressing film 17, the seed layer 16a, and the wiring connection portion 16b deposited on the interlayer insulating film 15 are removed, and the surface on the junction interface side is flattened until the surface of the interlayer insulating film 15 is exposed. By the above described process, the first semiconductor member 1 is formed.

Subsequently, a method of manufacturing the second semiconductor member 2 will be described. The second semiconductor member 2 may be formed by the same method as that for the first semiconductor member 1. That is, on the semiconductor substrate 20, the insulating film 21, the wiring portions 22, the first diffusion suppressing film 23, and the second diffusion suppressing film 24 are formed. Next, above the surface of the semiconductor substrate 20 (on the second diffusion suppressing film 24), the interlayer insulating film 25 is formed. Subsequently, in the interlayer insulating film 25, groove patterns (openings) are formed. Then, inside the groove patterns, the wiring connection portions 26 are formed. Thereafter, the surface on the junction interface side is polished away until the surface of the interlayer insulating film 25 is exposed. In this way, the second semiconductor member 2 is formed.

The first semiconductor member 1 and the second semiconductor member 2 formed as described above are aligned and bonded together such that the wiring connection portions 16 and the wiring connection portions 26 come into contact with each other. FIG. 11 illustrates a state where a misalignment has occurred between conductor portions 16 and 26 of first semiconductor member 1 and second semiconductor member 26 during bonding together of the first semiconductor member 1 and the second semiconductor member 2. As a result as illustrated in FIG. 11, regions where the wiring connection portions 16 and the interlayer insulating film 25 are in contact with each other, and regions where the wiring connection portions 26 and the interlayer insulating film 15 are in contact with each other are occur.

To bond together the first semiconductor member 1 and the second semiconductor member 2, they are thermally processed by an annealing process or the like while in contact with one another, such that the wiring connection portions are joined at the junction interface. As a result, the electronic circuit formed in the first semiconductor member 1 is electrically connected to the electronic circuit formed in the second semiconductor member 2. During the thermal process, the first semiconductor member 1 and the second semiconductor member 2 are heated, for example, from 100° C. to 400° C.

In a case where a misalignment has occurred during bonding of the first semiconductor member 1 and the second semiconductor member 2, due to the above described thermal process, as illustrated in FIG. 12, at the junction interface of the first semiconductor member 1 and the second semiconductor member, the first barrier films 31 are formed in the regions where the wiring connection portions 16 and the interlayer insulating film 25 are in contact with each other, and the second barrier films 32 are formed in the regions where the wiring connection portions 26 and the interlayer insulating film 15 are in contact with each other. As a result, it is possible to suppress diffusion of Cu from the wiring connection portions 16 into the interlayer insulating film 25 while suppressing Cu from diffusing from the wiring connection portions 26 into the interlayer insulating film 15.

Also, if the thermal process is performed, the metal element α contained in the seed layer 16a diffuses into the wiring connection portion 16b, such that the seed layer 16a and the wiring connection portion 16b are integrated, whereby the wiring connection portions 16 are formed with a single layer structure. Further, in the regions where the wiring connection portions 16 and the interlayer insulating film 25 are in contact with each other, the metal element α having diffused into the wiring connection portions 16 reacts with the predetermined elements (such as Si, C, F, and O) contained in the interlayer insulating film 25, whereby the first barrier films 31 are formed in a self-aligning way, i.e., only at the locations where the interlaying insulating film is in contact with a wiring portion, so as to suppress diffusion of Cu contained in the wiring connection portions 16 into the interlayer dielectric layer. That is, by the thermal process, the first barrier films 31 are automatically formed in the regions where the wiring connection portions 16 and the interlayer insulating film 25 are in contact with each other. A part of the metal element α having not reacted (having not formed the first barrier films 31) during the thermal process remains as it is in the wiring connection portions 16.

The second barrier films 32 are also formed similarly to the first barrier films 31. That is, the metal element β contained in the seed layer reacts with the predetermined elements contained in the interlayer insulating film 15, whereby the second barrier films 32 are formed in a self-aligning way in the regions where the wiring connection portions 26 and the interlayer insulating film 15 are in contact with each other.

As described above, according to the method of manufacturing the semiconductor device according to the present embodiment, since the predetermined metal elements are added to the wiring connection portions, it is possible to easily form the barrier films in situ, in a self-aligning way so as to suppress diffusion of Cu. Therefore, it is possible to improve the electrical characteristics and reliability of the semiconductor device, without process addition or process change in a process of manufacturing a semiconductor device. Also, it is possible to selectively form the barrier films 31 and 32 for suppressing diffusion of Cu, in a self-aligning way, in the regions where the wiring connection portions 16 and the interlayer insulating film 25 are in contact with each other, and in the regions where the wiring connection portions 26 and the interlayer insulating film 15 are in contact with each other, respectively, and not in areas where the wiring connection portions 16 and 26 are in contact with each other. Therefore, it is possible to lower the permittivity of the interlayer insulating films 15 and 16 as compared to a case of forming barrier films of SiN or the like on the entire surfaces of the interlayer insulating films 15 and 25. Also, since it is extraneous to use an additional insulating material for suppressing diffusion of Cu to form the interlayer insulating films, it is possible to reduce the cost.

Also, in the present embodiment, after the wiring connection portions 16 are formed, the surface of the first semiconductor member 1 is planarized such as by polishing. However, before planarization is performed, a thermal process such as an annealing process may be performed on the first semiconductor member 1. As a result, it is possible to improve the crystal state of the wiring connection portions 16, thereby improving the chemical and physical stability of the wiring connection portions 16. however, by the thermal process, oxide films of the metal element α are formed on the surfaces of the wiring connection portions 16, and the metal element a diffuses into the surface regions of the wiring connection portions 16. Since portions of the wiring connection portions 16 containing the metal element α are removed by CMP, the amount of metal element α contained in the wiring connection portions 16 after the CMP is less than the amount of metal element α added during the forming of the wiring connection portions 16. For this reason, it is preferable to add an extra amount of metal element α in view of an amount of metal element α to be removed by the CMP. The oxide films of the metal element α formed by the thermal process may be removed during the planarizing step.

Also, the first semiconductor member 1 may not include the third diffusion suppressing film 17. In this case, during the thermal process, the metal element α contained in the wiring connection portions 16 reacts with the predetermined elements contained in the interlayer insulating film 15, whereby barrier films are formed in a self-aligning way in regions where the wiring connection portions 16 and the interlayer insulating film 15 are in contact with each other. Therefore, it is possible to suppress Cu from diffusing from the wiring connection portions 16 into the interlayer insulating film 15.

Also, the first semiconductor member 1 may not include the first diffusion suppressing film 13 and the second diffusion suppressing film 14, and the wiring portions 12 may contain the metal element α. In this case, during the thermal process, the metal element α contained in the wiring portions reacts with predetermined elements contained in the insulating film 11, whereby barrier films for suppressing diffusion of Cu are formed in a self-aligning way in regions where the wiring portions 12 and the insulating film 11 are in contact with each other. Therefore, it is possible to suppress diffusion of Cu from the wiring portions 12 into the insulating film 11. Further, during the thermal process, the metal element α contained in the wiring portions 12 reacts with the predetermined element contained in the interlayer insulating film 15, whereby barrier films for suppressing diffusion of Cu are formed in a self-aligning way in regions where the wiring portions 12 and the interlayer insulating film 15 are in contact with each other. Therefore, it is possible to suppress Cu from diffusing from the wiring portions 12 into the interlayer insulating film 15.

Also, the wiring portions 16, 26 can be provided with misalignment in mind. For example the wiring portion of one of the semiconductor members 1, 2, such as wiring portion 26 of semiconductor member 2, is provided having a smaller exposed area in the interlayer insulating film 25 than the exposed area of wiring portion 16 in interlayer insulating layer 15, the entire surfaces of the wiring connection portions 26 of the second semiconductor member 2 on the junction interface side will be joined with the surfaces of the wiring connection portions 16 of the first semiconductor member 1 on the junction interface side as illustrated in FIG. 13. As the wiring connection portions 26 and the interlayer insulating film 15 do not come into contact with each other, the second barrier films 32 become extraneous. Therefore, in this case, the wiring connection portions 26 of the second semiconductor member 2 may not contain the metal element β.

Also, although the wiring connection portions 26 and the interlayer insulating film 15 come into contact with each other as illustrated in FIG. 1, in a case where the wiring connection portions 26 of the second semiconductor member 2 are formed using Al or the like as a main component, and do not contain Cu, diffusion of Cu from the wiring connection portions 26 does not occur. Therefore, the second barrier films 32 become extraneous. Therefore, in this case, the wiring connection portions 26 need not contain the metal element β.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first semiconductor member that includes a first insulating film, and a first wiring film in the first insulating film, the surface of which is exposed in the first insulating film;
a second semiconductor member that includes a second insulating film, and a second wiring film in the second insulating film, the surface of which is exposed in the second insulating film, the first and second semiconductor devices joined together; and
a first barrier film which forms a barrier to diffusion of the material of the first wiring film into the second insulating film, the first barrier film formed of a compound of a metal element of the first wiring film and an element of the second insulating film in a region where the first wiring film and the second insulating film are in contact with each other at the junction interface of the first semiconductor member and the second semiconductor member.

2. The semiconductor device according to claim 1, wherein
the metal element is added to the first wiring film during manufacturing of the first semiconductor member.

3. The semiconductor device according to claim 1, wherein
the first wiring film contains Cu as the primary component thereof.

4. The semiconductor device according to claim 1, wherein
the predetermined metal element includes at least one metal element selected from a group consisting of Mn, V, Zn, Nb, Zr, Cr, Y, Tc, and Re.

5. The semiconductor device according to any one of claim 1, wherein
the elements contained in the second insulating film include O and at least one element selected from a group consisting of Si, C, and F.

6. The semiconductor device according to claim 1, wherein
the second insulating film contains SiO₂ or SiOC as the primary component thereof.

7. The semiconductor device according to claim 1, wherein
where the metal element is represented by α, the first barrier film contains at least one compound selected from a group consisting of αₓO_{y}, αₓSi_{y}O_{z}, αₓC_{y}O_{z}, and αₓF_{y}O_{z}.

8. The semiconductor device according to claim 1, wherein
the first barrier film contains MnxSiyO₂.

9. A method of manufacturing a semiconductor device, comprising:
bonding a first semiconductor member which includes a first insulating film, and a first wiring film in the first insulating film with the surface thereof exposed in the first insulating film, and which contains a primary element and an first additional metal element, and a second semiconductor member which includes a second insulating film, and a second wiring film in the second insulating film with the surface thereof exposed in the second insulating film, such that the first wiring film and the second wiring film come into contact with each other;
performing a thermal process on the first semiconductor member and the second semiconductor member to bond the first semiconductor member and the second semiconductor member to each other to join the first wiring film to the second wiring film; and
if the first wiring film and the second insulating film are in contact with each other, forming a self-aligned barrier film in a region where the first wiring film and the second insulating film are in contact with each other, so as to contain a compound of the first additional metal element contained in the first wiring film and the element contained in the second insulating film.

10. The method of claim 9, further comprising:
providing a primary element and a second additional metal element in the second wiring film; and
during bonding of the first semiconductor member to the second semiconductor member, if the second wiring film and the first insulating film are in contact with each other, forming a self-aligned barrier film in a region where the second wiring film and the first insulating film are in contact with each other, so as to contain a compound of the second additional metal element contained in the second wiring film and the elements contained in the first insulating film.

11. The method of claim 9, wherein the area of the second wiring film exposed in the second insulating film is smaller than the area of the first wiring film exposed in the first insulating film.

12. The method of claim 9, wherein the first additional metal element is one or mere of Mn, V, Zn, Nb, Zr, Cr, Y, Tc, and Re.

13. The method of claim 9, wherein the first additional metal element is one or more of Mn, V, Zn, Nb, Zr, Cr, Y, Tc, and Re; and
the second additional metal element is a different one or more of Mn, V, Zn, Nb, Zr, Cr, Y, Tc, and Re than that of the first additional metal element.

14. The method of claim 9, wherein the second insulating film is an oxide of one or more of Si, SiC, and SiF.

15. A semiconductor device, comprising:
a first semiconductor member having first insulating layer and a first wiring layer exposed at a surface of the first insulating layer;
a second semiconductor member having second insulating layer and a second wiring layer exposed at a surface of the second insulating layer, wherein the first semiconductor member and the second semiconductor are joined together such that the first and second wiring layers are bonded together and a portion of the first wiring layer overlies the second insulating film; and
a diffusion barrier layer formed between the first wiring layer and the second insulating layer comprising elements of the first wiring layer and the second insulating layer.

16. The semiconductor device of claim 15, wherein the first wiring layer comprises a primary metal element and a first additional metal element, the element of the insulating layer comprising the first additional element and the material of the second insulating layer.

17. The semiconductor device of claim 16, wherein first additional metal element is one or more of Mn, V, Zn, Nb, Zr, Cr, Y, Tc, and Re.

18. The semiconductor device of claim 15, wherein the barrier film is self aligned to the overlap region of the first wiring layer and the second insulating film.

19. The semiconductor device of claim 15, wherein the second insulating film is an oxide of one or more of Si, SiC, and SiF.

20. The semiconductor device of claim 15, wherein the first wiring layer is copper.
